(19) United States
(12) Patent Application Publication
(10) Pub. No.: US 2017/0320994 A1
(43) Pub. Date: Nov. 9, 2017

(54) EPOXY RESIN COMPOSITION AND CURED PRODUCT THEREOF

(71) Applicant: DIC CORPORATION, Tokyo (JP)

(72) Inventors: Kazuo Arita, Ichihara-shi (JP); Tatsuya Okamoto, Ichihara-shi (JP); Kazuhisa Yamoto, Ichihara-shi (JP); Yutaka Sato, Ichihara-shi (JP)

(73) Assignee: DIC CORPORATION, Tokyo (JP)

(21) Appl. No.: 15/512,637

(22) PCT Filed: Sep. 24, 2015
(86) PCT No.: PCT/JP2015/076889

§ 371 Date: Mar. 20, 2017

(30) Foreign Application Priority Data
Oct. 1, 2014 (JP) 2014-203032

(51) Int. Cl. C08G 14/10; C09K 5/14; C09K 21/14; H01L 23/29; C08L 63/04; H05K 1/03; C08J 5/24; C08L 61/28; H05K 3/18; H05K 3/00; H05K 3/42

(52) U.S. Cl. CPC C08G 14/10; C08J 5/24; C09K 5/14; C09K 21/14; H01L 23/295; C08L 61/28; C08L 63/04; H05K 1/0326; C08J 2361/28; C08J 2363/04; C08J 2461/28; C08J 2463/04; C08L 2201/02; C08L 2201/08; H05K 3/005; H05K 3/42; H05K 3/18

(57) ABSTRACT

A triazine ring-containing phenol resin obtained by reacting melamine, para-alkylphenol, and formalin is used to provide an epoxy resin composition capable of providing a cured product with excellent flame retardancy, excellent dielectric characteristics such as a low dielectric tangent and a low dielectric constant, and excellent thermal conductivity, a cured product thereof, and a prepreg, a circuit board, a build-up film, a build-up board, a semiconductor sealing material, a semiconductor device, a fiber reinforced composite material, and a formed article using the epoxy resin composition.

### TECHNICAL FIELD

The present invention relates to an epoxy resin composition which provides a cured product with excellent flame retardancy and heat resistance, excellent dielectric characteristics such as a low dielectric tangent and a low dielectric constant, and excellent thermal conductivity.

### BACKGROUND ART

As circuit board materials for electronic devices, a prepreg obtained by impregnating glass cloth with a thermosetting resin such as an epoxy resin, a benzoxazine resin, or a bismaleimide-triazine (BT) resin and heating and drying the glass cloth, a laminated plate obtained by heating and curing the prepreg, and a multilayer plate obtained by combining the laminated plate and the prepreg and then heating and curing the resultant are widely used.

In recent years, particularly applications for advanced materials in these various applications, further improvement in performance typified by heat resistance, dielectric characteristics, and moisture resistance reliability has been required. From the viewpoint of environmental harmony, movement for eliminating halogen-based flame retardants has been further promoted and particularly development of materials which are free from halogen and have excellent flame retardancy has been strongly demanded.

In these circumstances, a technology of using a triazine ring-containing phenol resin obtained by reacting an amino group-containing triazine compound, phenols, and aldehydes with a curing agent for an epoxy resin has been suggested as a thermosetting system which is free from halogen and exhibits excellent flame retardancy (for example, see PTL 1 described below).

However, although the triazine ring-containing phenol resin exhibits excellent flame retardancy when the triazine ring-containing phenol resin combines with a phosphorus-based flame retardant, the triazine ring-containing phenol resin does not sufficiently exhibit flame retardancy if an additive flame retardant or a flame retardant promotor is not combined. In addition, the tendency of high frequency in electronic components in recent years is significant, and resin materials with a lower dielectric constant or a lower dielectric tangent are required for insulating materials such as a semiconductor sealing material, a copper clad laminated plate, and a build-up film, but the triazine ring-containing phenol resin does not fully satisfy the required level.

In synthesis of the triazine ring-containing phenol resin, a method of using ortho-cresol as phenols is also disclosed. This method contributes to a decrease in dielectric constant, but has a problem of solubility in a solvent so that the use thereof for a varnish is restricted.

As described above, materials do not have high flame retardancy, high heat resistance, a low dielectric constant, and a low dielectric tangent which are enough to withstand the use for advanced materials, and the materials cannot be used for the advanced materials.

### CITATION LIST

### Patent Literature

[PTL 1] JP-A-11-21419

### SUMMARY OF INVENTION

### Technical Problem

An object of the present invention is to provide an epoxy resin composition which provides a cured product with excellent flame retardancy and heat resistance, excellent dielectric characteristics such as a low dielectric tangent and a low dielectric constant, and excellent thermal conductivity and a cured product thereof.

### Solution to Problem

As a result of intensive research conducted by the present inventors in order to solve the above-described problems, it was found that an epoxy resin composition which provides a cured product with excellent flame retardancy and heat resistance, excellent dielectric characteristics such as a low dielectric tangent and a low dielectric constant, and excellent thermal conductivity can be provided by using a triazine ring-containing phenol resin obtained by reacting para-alkylphenol, melamine, and formalin as a curing agent for an epoxy resin, thereby completing the present invention.

In other words, the present invention relates to a triazine ring-containing phenol resin including: a structural site α represented by the following Structural Formula (I) and a structural site β represented by the following Structural Formula (II), as repeating structural units.

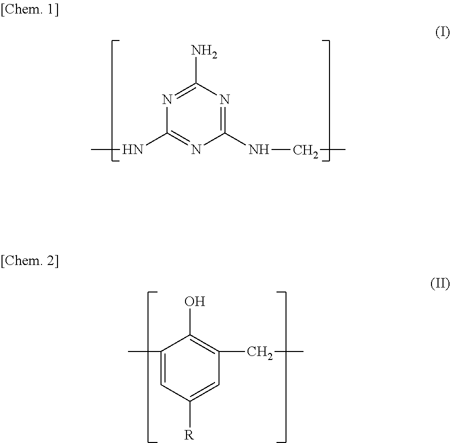

In the formula, R represents an alkyl group having 1 to 6 carbon atoms.

Further, the present invention relates to an epoxy resin composition that contains an epoxy resin and the triazine ring-containing phenol resin as indispensable components.

Further, the present invention relates to a cured product obtained by curing the epoxy resin composition; a prepreg obtained by impregnating a reinforcing base material with the epoxy resin composition diluted with an organic solvent and then semi-curing the obtained base material impregnated with the epoxy resin composition; a circuit board obtained by laminating the prepreg formed to have a plate shape and copper foil on each other and heating, pressing, and forming the laminated plate; a build-up film obtained by coating a base material film with the epoxy resin composition diluted with an organic solvent and drying the film; a build-up board obtained by forming irregularities on a circuit board, on which a circuit is formed and which is obtained by being coated with the build-up film and heating and curing the coated film, and performing a plating treatment on the circuit board; a semiconductor sealing material containing the epoxy resin composition and an inorganic filling material; a semiconductor device obtained by heating and curing the semiconductor sealing material; a semiconductor device obtained by heating and curing the semiconductor sealing material; a fiber reinforced composite material containing the epoxy resin composition and a reinforcing fiber; and a formed article formed by curing the fiber reinforced composite material.

### Advantageous Effects of Invention

According to the present invention, it is possible to provide an epoxy resin composition which provides a cured product with excellent flame retardancy and heat resistance, excellent dielectric characteristics such as a low dielectric tangent and a low dielectric constant, and excellent thermal conductivity and a cured product thereof.

Accordingly, the epoxy resin composition of the present invention is extremely useful as a resin composition for coping with high density mounting, high frequency correspondence, and high speed calculation in a case where the epoxy resin composition is used in the field of electronic materials such as a resin composition for a printed circuit board, a resin composition for a sealing material for an electronic component, resist ink, or conductive paste. Further, since the obtained formed and cured product has excellent flame retardancy, heat resistance, thermal conductivity, a low dielectric tangent, and a low dielectric constant, can be used for the above-described applications, and satisfies high level requirements for adhesives, composite materials, and the like, the formed and cured product is applicable to the fields for which high reliability is required.

In addition, the triazine ring-containing phenol resin of the present invention also has excellent solubility in a solvent.

### DESCRIPTION OF EMBODIMENTS

Hereinafter, the present invention will be described in detail.

<Epoxy Resin>

An epoxy resin (hereinafter, referred to as an “epoxy resin (A)”) used for a curable resin composition of the present invention will be described. Examples of the epoxy resin (A) include a bisphenol A type epoxy resin, a bisphenol F type epoxy resin, a bisphenol E type epoxy resin, a bisphenol S type epoxy resin, a bisphenol sulfide type epoxy resin, a biphenyl type epoxy resin, a tetramethyl biphenyl type epoxy resin, a polyhydroxy naphthalene type epoxy resin, a phenol novolak type epoxy resin, a cresol novolak type epoxy resin, a bisphenol A novolak type epoxy resin, a triphenylmethane type epoxy resin, a tetraphenyl ethane type epoxy resin, a dicyclopentadiene-phenol addition reaction type epoxy resin, a phenol aralkyl type epoxy resin, a biphenyl aralkyl type epoxy resin, a biphenyl novolak type epoxy resin, a naphthol novolak type epoxy resin, a naphthol aralkyl type epoxy resin, a naphthol-phenol co-condensed novolak type epoxy resin, a naphthol-cresol co-condensed novolak type epoxy resin, a biphenyl-modified phenol type epoxy resin (polyhydric phenol type epoxy resin in which a phenol skeleton is connected with a biphenyl skeleton through a bismethylene group), a biphenyl-modified naphthol type epoxy resin (polyhydric naphthol type epoxy resin in which a naphthol skeleton is connected with a biphenyl skeleton through a bismethylene group), an alkoxy group-containing aromatic ring-modified novolak type epoxy resin (compound in which a glycidyl group-containing aromatic ring is connected with an alkoxy group-containing aromatic ring through formaldehyde), a phenylene ether type epoxy resin, a naphthylene ether type epoxy resin, an aromatic hydrocarbon formaldehyde resin-modified phenol resin type epoxy resin, and a xanthene type epoxy resin. These may be used alone or in combination of two or more kinds thereof.

Among these, from the viewpoint of obtaining a cured product with excellent heat resistance, a phenol novolak type epoxy resin, a cresol novolak type epoxy resin, a bisphenol A novolak type epoxy resin, a polyhydroxy naphthalene type epoxy resin, a triphenylmethane type epoxy resin, a tetraphenyl ethane type epoxy resin, a biphenyl novolak type epoxy resin, a naphthol novolak type epoxy resin, a naphthol-phenol co-condensed novolak type epoxy resin, a naphthol-cresol co-condensed novolak type epoxy resin, a phenylene ether type epoxy resin, a naphthylene ether type epoxy resin, and a xanthene type epoxy resin are preferable.

Further, from the viewpoint of obtaining a cured product with excellent dielectric characteristics, a dicyclopentadiene-phenol addition reaction type epoxy resin, a naphthol novolak type epoxy resin, a phenol aralkyl type epoxy resin, a biphenyl aralkyl type epoxy resin, a naphthol aralkyl type epoxy resin, a naphthol-phenol co-condensed novolak type epoxy resin, a naphthol-cresol co-condensed novolak type epoxy resin, a biphenyl-modified phenol type epoxy resin (polyhydric phenol type epoxy resin in which a phenol skeleton is connected with a biphenyl skeleton through a bismethylene group), a biphenyl-modified naphthol type epoxy resin (polyhydric naphthol type epoxy resin in which a naphthol skeleton is connected with a biphenyl skeleton through a bismethylene group), an alkoxy group-containing aromatic ring-modified novolak type epoxy resin (compound in which a glycidyl group-containing aromatic ring is connected with an alkoxy group-containing aromatic ring through formaldehyde), an aromatic hydrocarbon formaldehyde resin-modified phenol resin type epoxy resin, and a naphthylene ether type epoxy resin are preferable.

A phenol resin (hereinafter, referred to as a “phenol resin (B)”) used in the present invention is a triazine ring-containing phenol resin obtained by reacting para-alkylphenol, melamine, and formalin. Specifically, the phenol resin is a mixture of a condensate of para-alkylphenol, melamine, and formalin, a condensate of melamine and formalin, a condensate of para-alkylphenol and formalin, para-alkylphenol, and melamine.

In the mixture described above, from the viewpoint of excellent flame retardancy, the content of a bifunctional compound represented by the following Structural Formula (III) is preferably in a range of 1% to 12%.

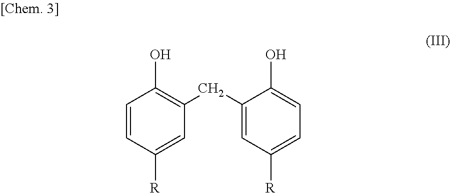

In the formula, R represents an alkyl group having 1 to 6 carbon atoms.

Further, from the viewpoint that a dielectric constant and a dielectric tangent are excellent, the molecular weight distribution (Mw/Mn) calculated based on a GPC measurement is preferably in a range of 1.35 to 1.85.

Moreover, the content of the bifunctional compound of the present invention is a value calculated from the area ratio of a GPC chart to be measured under the following conditions. In addition, the molecular weight distribution (Mw/Mn) is a value measured under the following GPC measurement conditions.

<GPC Measurement>

The measurement is carried out under the following conditions.

Measuring device: “HLC-8320 GPC”, manufactured by TOSOH CORPORATION

Column: Guard Column “HXL-L”, manufactured by TOSOH CORPORATION+“TSK-GEL G2000HXL”, manufactured by TOSOH CORPORATION+“TSK-GEL G2000HXL”, manufactured by TOSOH CORPORATION+“TSK-GEL G3000HXL”, manufactured by TOSOH CORPORATION+“TSK-GEL G4000HXL”, manufactured by TOSOH CORPORATION

Detector: RI (differential refractometry) detector

Data processing: “EcoSEC-WS VERSION 1.12”, manufactured by TOSOH CORPORATION

Measurement conditions: column temperature of 40° C., tetrahydrofuran used as developing solvent, flow rate of 1.0 ml/min

Standard: The following monodisperse polystyrene having a known molecular weight is used in conformity with the measurement manual of “EcoSEC-WS VERSION 1.12” described above.

(Polystyrene to be Used)

“A-1000” manufactured by TOSOH CORPORATION

“A-5000” manufactured by TOSOH CORPORATION

“F-2” manufactured by TOSOH CORPORATION

“F-4” manufactured by TOSOH CORPORATION

“F-20” manufactured by TOSOH CORPORATION

Sample: 1.0% by mass of tetrahydrofuran solution in terms of resin solid, which is filtered using microfilter (50 μl).

Here, the condensate of para-alkylphenol, melamine, and formalin is (Y) having a structural site α represented by the following Structural Formula (I); and a structural site β represented by the following Structural Formula (II), as repeating structural units.

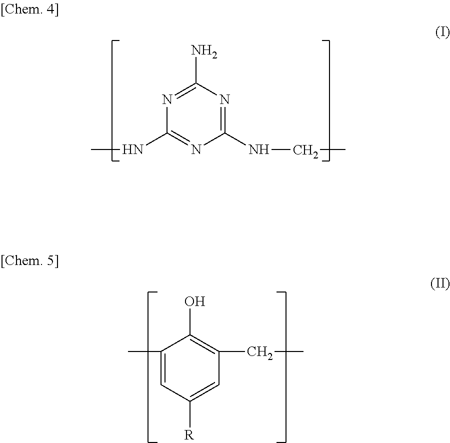

(In the formula, R represents an alkyl group having 1 to 6 carbon atoms.)

Therefore, the present invention relates to an epoxy resin composition containing the epoxy resin (A) and (Y) as indispensable components.

R in Structural Formulae (II) and (III) represents an alkyl group having 1 to 6 carbon atoms, and examples thereof include a methyl group, an ethyl group, a normal propyl group, an isopropyl group, a normal butyl group, a secondary butyl group, a tertiary butyl group, a pentyl group, a hexyl group, and a cyclohexyl group. Among these, from the viewpoint of excellent various performances of heat resistance, dielectric characteristics, and flame retardancy, a tertiary butyl group is preferable. In other words, it is preferable to use para-tertiary butyl phenol as the para-alkylphenol.

The above-described triazine ring-containing phenol resin is obtained by reacting respective components of para-alkylphenol, melamine, and formalin. Specifically, the triazine ring-containing phenol resin is obtained using a method of reacting para-alkylphenol, melamine, and formalin in the presence or absence of a catalyst. The reaction sequence of respective raw materials is not particularly limited. Accordingly, melamine may be added after para-alkylphenol reacts with formalin or, reversely, para-alkylphenol may be added for the reaction after formalin reacts with melamine. Alternatively, all raw materials are added for the reaction at the same time.

At this time, the molar ratio of formalin to para-alkylphenol is not particularly limited, and formalin/para-alkylphenol is preferably in a range of 0.1 to 1.1 (molar ratio) and more preferably in a range of 0.2 to 0.8.

From the viewpoints that the reaction system is uniform, the reactant becomes uniform, the crosslinking density of a cured product to be obtained is moderate, and the physical properties of the cured product is excellent, the molar ratio of melamine to para-alkylphenol (melamine/para-alkylphenol) is preferably in a range of 0.03 to 1.50 (molar ratio) and particularly preferably in a range of 0.03 to 0.50 (molar ratio).

In a case where a catalyst is used, a hydroxide of alkaline earth metal and alkali metal such as sodium hydroxide, potassium hydroxide, or barium hydroxide, oxides of these, ammonia, primary to tertiary amines, hexamethylenetetramine, or sodium carbonate may be used as a basic catalyst; and an inorganic acid such as hydrochloric acid, sulfuric acid, sulfonic acid, or phosphoric acid, an organic acid such as oxalic acid or acetic acid, Lewis acid, or divalent metal salt such as zinc acetate may be used as an acidic catalyst. Here, in a case where the epoxy resin composition of the present invention is used as a resin for an electric and electronic material, it is preferable that an inorganic substance such as a metal does not remain as a catalyst residue. Therefore, it is preferable that amines such as triethylamine are used as a basic catalyst and an organic acid is used as an acidic catalyst.

Moreover, the above-described reaction may be performed in the presence of various solvents from the viewpoint of controlling the reaction. If necessary, neutralization, water washing, and then removal of impurities such as salts may be carried out. However, impurities may not be removed in a case where a catalyst is not used or amines are used as a catalyst.

After the reaction is finished, condensed water, unreacted formalin, para-alkylphenol, a solvent, and the like are removed according to a conventional method such as atmospheric distillation or vacuum distillation. At this time, it is preferable that the triazine ring-containing phenol resin which does not substantially contain a methylol group is used. For this reason, it is preferable that a heat treatment is performed at 120° C. or higher. In addition, a methylol group can be eliminated by sufficiently taking time if the heat treatment is performed at a temperature of 120° C. or higher. However, in order to efficiently eliminate a methylol group, it is preferable that the heat treatment is performed at a higher temperature, preferably, 150° C. or higher. At this time, it is preferable that evaporation is carried out together with the heating at a high temperature according to a conventional method used when a novolak resin is obtained.

The content ratio of unreacted para-alkylphenol remaining in the triazine ring-containing phenol resin obtained in the above-described manner is not limited at all, and is preferably 5% by mass or less and more preferably 3% by mass or less from the viewpoint that the heat resistance or the moisture resistance of a cured product becomes excellent.

Particularly, the softening point of the triazine ring-containing phenol resin is preferably in a range of 75° C. to 200° C. and more preferably in a range of 75° C. to 180° C. from the viewpoint that the balance between the flame retardancy and the heat resistance is excellent. The softening point here is a value measured by a ring and ball method (in conformity with “JIS K7234-86”, temperature rising rate of 5° C./min).

From the viewpoint of curability and heat resistance of a cured product, it is preferable that the blending ratio between the epoxy resin (A) and the phenol resin (B) is a ratio in which the molar ratio (epoxy group/phenolic hydroxyl group) of the epoxy group in the epoxy resin (A) to the phenolic hydroxyl group in the phenol resin (B) is in a range of 5 to 0.5.

Other thermosetting resins may be used together for the epoxy resin composition of the present invention in addition to the above-described epoxy resin (A) and the triazine ring-containing phenol resin (B) obtained by reacting para-alkylphenol, melamine, and formalin.

Examples of the above-described other thermosetting resins include a cyanate ester resin, a benzoxazine resin, a maleimide compound, an active ester resin, a vinylbenzyl compound, an acrylic compound, and a copolymer of styrene and a maleic anhydride. In a case where the above-described other thermosetting resins are used together, the amount of the other thermosetting resins to be used is not particularly limited unless the effects of the present invention are impaired, and the amount thereof is preferably in a range of 1 to 50 parts by weight based on 100 parts by mass of the thermosetting resin composition.

Examples of the cyanate ester resin include a bisphenol A type cyanate ester resin, a bisphenol F type cyanate ester resin, a bisphenol E type cyanate ester resin, a bisphenol S type cyanate ester resin, a bisphenol M type cyanate ester resin, a bisphenol P type cyanate ester resin, a bisphenol Z type cyanate ester resin, a bisphenol AP type cyanate ester resin, a bisphenol sulfide type cyanate ester resin, a phenylene ether type cyanate ester resin, a naphthylene ether type cyanate ester resin, a biphenyl type cyanate ester resin, a tetramethyl biphenyl type cyanate ester resin, a polyhydroxy naphthalene type cyanate ester resin, a phenol novolak type cyanate ester resin, a cresol novolak type cyanate ester resin, a triphenylmethane type cyanate ester resin, a tetraphenyl ethane type cyanate ester resin, a dicyclopentadiene-phenol addition reaction type cyanate ester resin, a phenol aralkyl type cyanate ester resin, a naphthol novolak type cyanate ester resin, a naphthol aralkyl type cyanate ester resin, a naphthol-phenol co-condensed novolak type cyanate ester resin, a naphthol-cresol co-condensed novolak type cyanate ester resin, an aromatic hydrocarbon formaldehyde resin-modified phenol resin type cyanate ester resin, a biphenyl-modified novolak type cyanate ester resin, and an anthracene type cyanate ester resin. These may be used alone or in combination of two or more kinds thereof.

Among these cyanate ester resins, particularly from the viewpoint of obtaining a cured product with excellent heat resistance, a bisphenol A type cyanate ester resin, a bisphenol F type cyanate ester resin, a bisphenol E type cyanate ester resin, a polyhydroxy naphthalene type cyanate ester resin, a naphthylene ether type cyanate ester resin, and a novolak type cyanate ester resin are preferably used. From the viewpoint of obtaining a cured product with excellent dielectric characteristics, a dicyclopentadiene-phenol addition reaction type cyanate ester resin is preferable.

The benzoxazine resin is not particularly limited, and examples thereof include a reaction product (F-a type benzoxazine resin) of bisphenol F, formalin, and aniline, a reaction product (P-d type benzoxazine resin) of diamino diphenyl methane, formalin, and phenol, a reaction product of bisphenol A, formalin, and aniline, a reaction product of dihydroxy diphenyl ether, formalin, and aniline, a reaction product of diamino diphenyl ether, formalin, and phenol, a reaction product of a dicyclopentadiene-phenol addition type resin, formalin, and aniline, a reaction product of phenolphthalein, formalin, and aniline, and a reaction product of diphenyl sulfide, formalin, and aniline. These may be used alone or in combination of two or more kinds thereof.

As the maleimide compound, various compounds represented by any of the following Structural Formulae (i) to (iii) may be exemplified.

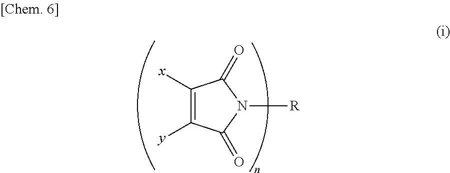

(In the formula, R represents an m-valent organic group, x and y each represent a hydrogen atom, a halogen atom, an alkyl group, or an aryl group, and n represents an integer of 1 or greater.)

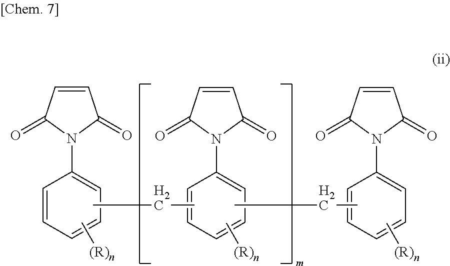

(In the formula, R represents a hydrogen atom, an alkyl group, an aryl group, an aralkyl group, a halogen atom, a hydroxyl group, or an alkoxy group, n represents an integer of 1 to 3, and m represents 0 to 10 which is the average of repeating units.)

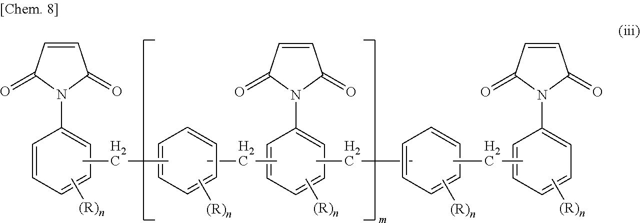

(In the formula, R represents a hydrogen atom, an alkyl group, an aryl group, an aralkyl group, a halogen atom, a hydroxyl group, or an alkoxy group, n represents an integer of 1 to 3, and m represents 0 to 10 which is the average of repeating units.)

These may be used alone or in combination of two or more kinds thereof.

The active ester resin is not particularly limited, but a compound having two or more ester groups with high reaction activity in a molecule, such as phenol esters, thiophenol esters, N-hydroxyamine esters, or esters of a heterocyclic hydroxy compound is preferably used. As the active ester resin, an active ester resin obtained by carrying out a condensation reaction of a carboxylic acid compound and/or a thiocarboxylic acid compound, and a hydroxy compound and/or a thiol compound is preferable. Particularly from the viewpoint of improving the heat resistance, an active ester resin obtained from a carboxylic acid compound or a halide thereof and a hydroxy compound is preferable and an active ester resin obtained from a carboxylic acid compound or a halide thereof, and a phenol compound and/or a naphthol compound is more preferable. Examples of the carboxylic acid compound include benzoic acid, acetic acid, succinic acid, maleic acid, itaconic acid, phthalic acid, isophthalic acid, terephthalic acid, pyromellitic acid, and a halide thereof. Examples of the phenol compound or the naphthol compound include hydroquinone, resorcin, bisphenol A, bisphenol F, bisphenol S, dihydroxy diphenyl ether, phenolphthalein, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzene triol, and a dicyclopentadiene-phenol addition type resin.

As the active ester resin, specifically, an active ester resin having a dicyclopentadiene-phenol addition structure, an active ester resin having a naphthalene structure, an active ester resin which is an acetylated product of a phenol novolak, or an active ester resin which is a benzoylated product of phenol novolak is preferable. Among these, from the viewpoint of contributing to improving peel strength, an active ester resin having a dicyclopentadiene-phenol addition structure or an active ester resin having a naphthalene structure is more preferable. More specifically, a compound represented by the following Formula (iv) may be exemplified as the active ester resin having a dicyclopentadiene-phenol addition structure.

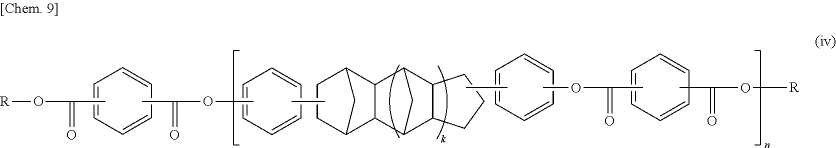

[In the formula, R represents a phenyl group or a naphthyl group, k represents 0 or 1, and n represents 0.05 to 2.5 which is the average of repeating units.]

From the viewpoints that the dielectric tangent of a cured product of the resin composition is decreased and the heat resistance is improved, it is preferable that R represents a naphthyl group, k represents 0, and n represents 0.25 to 1.5.

In addition to the phenol resin (B) as a curing agent for an epoxy resin, other curing agents (Z) for an epoxy resin, such as an amine-based compound, an amide-based compound, an acid anhydride-based compound, and a phenol-based compound, may be used together with the epoxy resin composition of the present invention unless the effects of the present invention are impaired. In this case, the curing agent (Z) can be used by replacing a part of the phenol resin (B) with the curing agent (Z). In other words, in a case where the curing agent (Z) is used together, the total proportion of active hydrogen in the curing agent (Z) and active hydrogen in the phenol resin (B) is preferably in a range of 0.2 to 2 with respect to 1 mole of the epoxy group in the epoxy resin (A). Further, the curing agent (Z) can be used at a proportion of 50% by mass or less with respect to the total mass of the phenol resin (B) and the curing agent (Z).

Examples of the amine-based compound which can be used here include meta-xylenediamine, diaminodiphenylmethane, diethylenetriamine, triethylenetetramine, diaminodiphenylsulfone, isophorone diamine, imidazole, a BF3-amine complex, and a guanidine derivative. Examples of the amide-based compound include dicyandiamide and a polyamide resin synthesized by a dimer of linolenic acid and ethylenediamine.

Examples of the acid anhydride-based compound include phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, and methylhexahydrophthalic anhydride.

In addition, examples of the phenol-based compound used as the curing agent (Z) include a phenol novolak resin, a cresol novolak resin, an aromatic hydrocarbon formaldehyde resin-modified phenol resin, a dicyclopentadiene phenol addition type resin, a phenol aralkyl resin, an α-naphthol aralkyl resin, a β-naphthol aralkyl resin, a biphenyl aralkyl resin, a trimethylolmethane resin, a tetraphenylolethane resin, a naphthol novolak resin, a naphthol-phenol co-condensed novolak resin, a naphthol-cresol co-condensed novolak resin, and an aminotriazine-modified phenol resin. In addition, the aminotriazine-modified phenol resin is a resin other than the phenol resin (B) of the present invention, and specific examples thereof include a copolymer of an amino group-containing triazine compound such as melamine or benzoguanamine, phenol, and formaldehyde.

Among these, particularly from the viewpoints of the cured product having a smaller linear expansion coefficient, being resistant to thermal impact and physical impact, and having excellent toughness, a polyhydric phenol-based compound is preferable and a phenol novolak resin, a cresol novolak resin, a phenol aralkyl resin, an α-naphthol aralkyl resin, a β-naphthol aralkyl resin, a biphenyl aralkyl resin, or an aminotriazine-modified phenol resin is preferable.

A curing accelerator (hereinafter, referred to as a “curing accelerator (C)”) can be suitably used for the epoxy resin composition of the present invention in order to cause a curing reaction between the epoxy resin (A) and the phenol resin (B) to rapidly proceed. Examples of the curing accelerator (C) which can be used here include imidazoles, tertiary amines, and tertiary phosphines.

Specific examples of the imidazoles include masked imidazoles in addition to 2-ethyl-4-methylimidazole, 2-methylimidazole, 2-ethylimidazole, 2,4-dimethylimidazole, 2-undecylimidazole, 2-heptadecylimidazole, 2-phenylimidazole, 2-phenyl-4-methylimidazole, 1-benzyl-2-methylimidazole, 2-phenyl-4,5-dihydroxymethylimidazole, 2-phenyl-4-methyl-5-hydroxymethylimidazole, 1-vinyl-2-methylimidazole, 1-propyl-2-methylimidazole, 2-isopropylimidazole, 1-cyanomethyl-2-methyl-imidazole, 1-cyanoethyl-2-ethyl-4-methylimidazole, 1-cyanoethyl-2-undecylimidazole, and 1-cyanoethyl-2-phenylimidazole.

Specific examples of the tertiary amines include trimethylamine, triethylamine, tripropylamine, tributylamine, tetramethylbutanediamine, tetramethylpentadiamine, tetramethylhexadiamine, triethylenediamine, N,N-dimethylbenzylamine, N,N-dimethylaniline, N,N-dimethyltoluidine, N,N-dimethylanisidine, pyridine, picoline, quinoline, N,N′-dimethylaminopyridine, N-methylpiperidine, N,N′-dimethylpiperazine, and 1,8-diazabicyclo-[5,4,0]-7-undecene (DBU).

Specific examples of the tertiary phosphines include trimethylphosphine, triethylphosphine, tripropylphosphine, tributylphosphine, triphenylphosphine, tris(p-tolyl)phosphine, dimethylphenylphosphine, and methyldiphenylphosphine.

Further, the amount of the curing accelerator (C) to be added can be suitably adjusted according to the target curing time and is preferably in a range of 0.01% to 2% by mass with respect to the total mass of the epoxy resin (A), the phenol resin (B), and the curing accelerator (C).

In addition to the above-described respective components, an organic solvent (hereinafter, referred to as an “organic solvent (D)”) can be used for the epoxy resin composition of the present invention according to the applications thereof. For example, in a case where the epoxy resin composition is used as a varnish for a copper clad laminated plate, the impregnation properties with respect to a base material are improved. In a case where the epoxy resin composition is used as an interlayer insulating material of a build-up printed circuit board, particularly, as a build-up film, coating properties with respect to a base material sheet become excellent. Examples of the organic solvent (D) which can be used here include alcoholic solvents such as methanol, ethanol, isopropyl alcohol, methyl cellosolve, ethyl cellosolve, and propylene glycol monomethyl ether, ketones such as acetone, methyl ethyl ketone, methyl isobutyl ketone, and cyclohexanone, acetates such as ethyl acetate, butyl acetate, cellosolve acetate, propylene glycol monomethyl ether acetate, and carbitol acetate, carbitols such as cellosolve and butyl carbitol, aromatic hydrocarbons such as toluene and xylene, dimethylformamide, dimethylacetamide, and N-methylpyrrolidone. Among these, propylene glycol monomethyl ether acetate and methyl ethyl ketone are preferable.

In the case where the epoxy resin composition is used as a varnish for a copper clad laminated plate, it is preferable that the amount of the organic solvent (D) to be used is set such that the non-volatile content in the composition is in a range of 50% to 70% by mass. Meanwhile, in a case where the epoxy resin composition is used as a varnish for a build-up film, it is preferable that the amount of the organic solvent (D) to be used is set such that the non-volatile content in the composition is in a range of 30% to 60% by mass.

In addition to the above-described components, an inorganic filling material, a modifier, or a flame retardancy-imparting agent may be suitably blended with the epoxy resin composition of the present invention according to the applications thereof.

Examples of the inorganic filling material used here include fused silica, crystalline silica, alumina, silicon nitride, aluminum hydroxide, and magnesium hydroxide. Here, the fused silica can be used in a crushed shape or spherical shape, but it is preferable that fused silica in a spherical shape is used in order to increase the amount of fused silica to be blended and suppress an increase in melt viscosity of a forming material. Further, in order to increase the amount of spherical silica to be blended, it is preferable that the particle size distribution of spherical silica is appropriately adjusted.

The desirable range of the blending ratio of the inorganic filling material varies depending on the applications or desired characteristic thereof. For example, in a case where the inorganic filling material is used for applications for a semiconductor sealing material, it is preferable that the blending ratio thereof is high from the viewpoints of the linear expansion coefficient or flame retardancy and the blending ratio thereof is preferably in a range of 65% to 95% by mass and particularly preferably in a range of 85% to 95% by mass with respect to the total amount of the epoxy resin composition. Moreover, in a case where the inorganic filling material is used for applications for conductive paste or a conductive film, a conductive filler such as silver powder or copper powder can be used.

Various resins can be used as a thermosetting resin and a thermoplastic resin used as the modifier, and examples thereof include a phenoxy resin, a polyamide resin, a polyimide resin, a polyether imide resin, a polyether sulfone resin, a polyphenylene ether resin, a polyphenylene sulfide resin, a polyester resin, a polystyrene resin, and a polyethylene terephthalate resin.

Examples of the flame retardancy-imparting agent include a halogen compound, a phosphorus atom-containing compound, a nitrogen atom-containing compound, and an inorganic flame retardant compound. Specific examples thereof include a halogen compound such as tetrabromobisphenol A type epoxy resin or a brominated phenol novolak type epoxy resin; a phosphorus atom-containing compound, for example, phosphate such as trimethyl phosphate, triethyl phosphate, tributyl phosphate, tri-2-ethylhexyl phosphate, tributoxyethyl phosphate, triphenyl phosphate, tricresyl phosphate, trixylenyl phosphate, cresyl diphenyl phosphate, xylenyl diphenyl phosphate, 2-ethylhexyl diphenyl phosphate, tris(2,6-dimethylphenyl)phosphate, or resorcin diphenyl phosphate, and a condensed phosphate compound such as ammonium polyphosphate, polyphosphoric acid amide, red phosphorus, guanidine phosphate, or dialkyl hydroxy methyl phosphonate; a nitrogen atom-containing compound such as melamine; and an inorganic flame retardant compound such as aluminum hydroxide, magnesium hydroxide, zinc borate, or calcium borate. However, since the epoxy resin composition of the present invention exhibits excellent flame retardant effects without using a halogen-based flame retardant which causes a high environmental load, it is preferable that a phosphorus atom-containing compound, a nitrogen atom-containing compound, or an inorganic flame retardant compound is used in a case where the above-described flame retardancy-imparting agent is used.

The conditions for thermal curing of the epoxy resin composition of the present invention are not particularly limited as long as the temperature thereof is higher than or equal to the temperature at which a resin component is softened, and the epoxy resin composition can be cured under conditions in which a typical phenol resin is cured. Further, the curing can be performed at a temperature of 120° C. to 250° C. Particularly, from the viewpoint of excellent formability, the temperature thereof is preferably in a range of 150° C. to 220° C.

As described above, the epoxy resin composition of the present invention described in detail above is useful as a resin composition for a copper clad laminated plate, an interlayer insulating material of a build-up printed circuit board, or a build-up film. In addition to these, the epoxy resin composition can be used for a resin composition for a sealing material of an electronic component, a resin composition for resist ink, a binder for a friction material, conductive paste, a resin casting material, an adhesive, and coating materials such as an insulating coating material.

As a method of producing a resin composition for a copper clad laminated plate from the epoxy resin composition of the present invention, specifically, a method of obtaining a varnish by blending the curing accelerator (C) and the organic solvent (D) as necessary with the epoxy resin (A) and the phenol resin (B) as indispensable components may be exemplified. Here, from the viewpoints of impregnation properties with respect to a fiber base material and productivity of a prepreg, the non-volatile content in the varnish is preferably in a range of 50% to 70% by mass.

Next, the following method is a specific example of the method of producing a copper clad laminated plate from the resin composition for a copper clad laminated plate.

A fiber base material such as paper, glass cloth, glass non-woven fabric, aramid paper, aramid cloth, glass mat, or glass roving cloth is impregnated with the varnish obtained according to the above-described method and the fiber base material is heated at a heating temperature in accordance with the type of solvent used, preferably a temperature of 50° C. to 170° C., thereby obtaining a prepreg which is a cured product. At this time, it is preferable that the blending ratio between the epoxy resin composition and the reinforcing base material is adjusted such that the resin content in the prepreg is typically in a range of 20% to 60% by mass.

The target copper clad laminated plate can be obtained by laminating the obtained prepreg, overlapping copper foil, and performing thermal pressing bonding. Here, a method of performing thermal pressing bonding under a temperature condition of 170° C. to 250° C. at a pressure of 1 to 10 MPa may be exemplified as the method of thermal pressing bonding. Further, it is preferable that the thermal pressing bonding is performed for 10 minutes to 3 hours.

In addition, the epoxy resin composition of the present invention is extremely useful as an interlayer insulating material of a build-up printed circuit board. The interlayer insulating material of a build-up printed circuit board can be prepared particularly using a method of blending the organic solvent (D) and the curing accelerator (C) as necessary with the epoxy resin (A) and the phenol resin (B) as indispensable components, among the methods of obtaining a varnish described above. Here, particularly from the viewpoints of coating properties or film formability, the non-volatile content in the varnish is preferably in a range of 30% to 60% by mass. Specifically, the following method may be exemplified as the method of producing a build-up board from the interlayer insulating material for a build-up board obtained in the above-described manner.

That is, a wiring board on which a circuit is formed is coated with the interlayer insulating material for a build-up board using a spray coating method or a curtain coating method, the coated material is cured, the wiring board is punched to form a predetermined through-hole as necessary and treated using a roughening agent, the surface thereof is washed with hot water, irregularities are formed as a result thereof, and then a metal such as copper is used to perform a plating treatment. An electroless plating treatment or an electrolytic plating treatment is preferable as the plating method, and examples of the roughening agent include an oxidizing agent, an alkali, and an organic solvent. A build-up board can be obtained by sequentially repeating such operations as desired and alternately building up and forming a resin insulating layer and a conductor layer having a predetermined circuit pattern. In this case, it is preferable that the punching for the through-hole is performed after the resin insulating layer serving as an outermost layer is formed. Further, when a roughened surface is formed by thermally pressing bonding a copper foil having a resin thereon, which is formed by semi-curing the resin composition on copper foil, to the wiring board on which a circuit is formed, in a temperature range of 170° C. to 250° C., the plating treatment process can be omitted in the preparation of a build-up board.

In addition, the interlayer insulating material of a build-up printed circuit board can be used not only as the above-described material being in the form of a coating material but also as a build-up film. The epoxy resin composition of the present invention is particularly useful as a build-up film because the resin component itself exhibits excellent heat resistance.

As a method of producing a build-up film from the epoxy resin composition of the present invention, a method of coating a support film with the epoxy resin composition of the present invention and forming a resin composition layer to obtain a film for a multilayer printed wiring plate may be exemplified.

In a case where the epoxy resin composition of the present invention is used as a build-up film, it is important that the film is softened under a temperature condition (typically in a range of 70° C. to 140° C.) for a laminate in a vacuum lamination method and fluidity (resin flow) in which a via hole or a through-hole present in a circuit board can be filled with a resin is exhibited at the same time with the lamination of the circuit board. In addition, it is preferable that the above-described respective components are blended with each other so that such characteristics are exhibited.

Here, the diameter of the through-hole of the multilayer printed wiring plate is typically in a range of 0.1 to 0.5 mm and the depth thereof is typically in a range of 0.1 to 1.2 mm, and it is preferable that the through-hole can be filled with a resin in the above-described range. Further, in a case where both surfaces of the circuit board are laminated, it is desirable that a half of the through-hole is filled with a resin.

According to the method of producing the film, specifically, the film can be produced by preparing the epoxy resin composition of the present invention in a varnish shape, coating the surface of a support film with the varnish-like composition, drying an organic solvent by heating, blowing hot air, or the like, and forming a layer of the epoxy resin composition.

The thickness of the layer to be formed is typically greater than or equal to the thickness of the conductor layer. Since the thickness of the conductor layer included in the circuit board is typically in a range of 5 to 70 μm, the thickness of the resin composition layer is preferably in a range of 10 to 100 μm.

Further, the layer of the present invention may be protected by a protective film described below. When the layer is protected by the protective film, adhesion of dust or damage to the surface of the resin composition layer can be prevented.

As the support film and the protective film, polyolefin such as polyethylene, polypropylene, or polyvinyl chloride, polyester such as polyethylene terephthalate (hereinafter, also abbreviated as “PET”) or polyethylene naphthalate, polycarbonate, polyimide, release paper, or metal foil such as copper foil or aluminum foil may be exemplified. In addition, the support film and the protective film may be subjected to a release treatment in addition to a mud treatment and a corona treatment.

The thickness of the support film is not particularly limited, but is typically in a range of 10 to 150 μm and preferably in a range of 25 to 50 μm. Further, the thickness of the protective film is preferably in a range of 1 to 40 μm.

After the above-described support film is laminated on the circuit board or heated and cured to form an insulating layer, the support film is peeled off. When the support film is peeled off after the film is heated and cured, adhesion of dust or the like during the curing process can be prevented. In a case where the support film is peeled off after the film is cured, the support film is typically subjected to a release treatment in advance.

Next, according to the method of producing a multilayer printed wiring plate using the film obtained in the above-described manner, for example, a protective film is peeled off in a case where the layers are protected by the protective film, and then the layers are laminated on one surface or the both surfaces of the circuit board using, for example, a vacuum lamination method such that the layers are directly in contact with the circuit board. The lamination method may be a batch type or a continuous type using a roll. Further, the film and the circuit board may be heated (pre-heated) as necessary before the layers are laminated.

It is preferable that the lamination is performed under conditions of a pressure bonding temperature (lamination temperature) of preferably 70° C. to 140° C., a pressure bonding pressure of preferably 1 to 11 kgf/cm² (9.8×10⁴ to 107.9×10⁴ N/m²), and an air pressure of 20 mmHg (26.7 hPa) or less, that is, under reduced pressure.

Further, in applications for the interlayer insulating material of the build-up printed circuit board or the build-up film, the epoxy resin composition of the present invention is particularly useful as an insulating material in a so-called substrate incorporating an electronic component formed by embedding a passive component such as a capacitor or an active component such as an IC chip in a substrate based on the characteristics of exhibiting excellent heat resistance in the present invention.

As described above, the epoxy resin composition of the present invention is useful as a resin composition for a copper clad laminated plate, an interlayer insulating material of a build-up printed circuit board, a build-up film, or the like from the viewpoints of providing a cured product with excellent flame retardancy and having excellent dielectric characteristics such as a low dielectric tangent and a low dielectric constant. The epoxy resin composition of the present invention can be used as a resin composition for a sealing material of an electronic component, a resin composition for a resist ink, a binder for a friction material, conductive paste, an adhesive, an insulating coating material, or a resin casting material in addition to those described above.

Examples of specific applications of the epoxy resin composition of the present invention in a case where the epoxy resin composition is used as a resin composition for a sealing material of an electronic component include a semiconductor sealing material, a tape-like sealant of a semiconductor, a potting type liquid sealant, a resin for underfilling, and an interlayer insulating film of a semiconductor.

The epoxy resin composition of the present invention may be adjusted to use as a semiconductor sealing material using, for example, a technique of premixing the epoxy resin (A), the phenol resin (B), and other additives such as a coupling agent and a release agent to be blended as necessary or an inorganic filling material and sufficiently mixing until the mixture becomes uniform using an extruder, a kneader, or a roll. In a case where the epoxy resin composition is used as a tape-like sealant of a semiconductor, a method of heating the resin composition obtained by the above-described technique, preparing a semi-cured sheet to obtain sealant tape, putting the sealant tape on a semiconductor chip, heating to a temperature range of 100° C. to 150° C., softening, and forming the sealant tape, and completely curing the sealant tape in a temperature range of 170° C. to 250° C. may be used.

As a method of using the epoxy resin composition of the present invention as a resin composition for resist ink, a method of adding the organic solvent (D), a pigment, talc, and a filler to the epoxy resin (A) and the phenol resin (B) to obtain a composition for resist ink, coating a printed circuit board with the obtained composition according to a screen printing system, and obtaining a resist ink cured product may be exemplified. Examples of the organic solvent (D) used here include methyl cellosolve, ethyl cellosolve, methyl cellosolve acetate, ethyl cellosolve acetate, cyclohexanone, dimethyl sulfoxide, dimethyl formamide, dioxolane, tetrahydrofuran, propylene glycol monomethyl ether acetate, and ethyl lactate.

In a case where the epoxy resin composition of the present invention is used for the binder for a friction material, the binder for a friction material can be produced by using a substance that generates formaldehyde by heating hexamethylenetetramine, paraformaldehyde, or the like in addition to the epoxy resin (A) and the phenol resin (B) and blending the curing accelerator (C). A friction material may be prepared using the binder for a friction material using a method of adding a filler or an additive to the above-described respective components and then thermally curing the components or a method of impregnating a fiber base material with the above-described respective components and thermally curing the fiber base material. Examples of the filler and the additive used here include silica, barium sulfate, calcium carbonate, silicon carbide, a cashew oil polymer, molybdenum disulfide, aluminum hydroxide, talc, clay, black lead, graphite, rubber grains, aluminum powder, copper powder, and brass powder.

In a case where the epoxy resin composition of the present invention is used as a potting type liquid sealant, the resin composition obtained by the above-described technique is dissolved in a solvent as necessary, a semiconductor chip or an electronic component is coated with the solvent, and then the coated surface may be directly cured.

As a method of using the epoxy resin composition of the present invention as a resin for underfilling, a compression flow method of coating a substrate or a semiconductor element with a varnish-like epoxy resin composition in advance, semi-curing and then heating the composition, bringing the semiconductor element into close contact with the substrate, and performing complete curing is exemplified.

As a method of using the epoxy resin composition of the present invention as an interlayer insulating material of a semiconductor, a method of preparing the composition by blending the curing accelerator (C) and a silane coupling agent in addition to the epoxy resin (A) and the phenol resin (B) and then coating a silicon substrate with the composition according to a spin coating method or the like may be exemplified. In this case, since the cured coating film is brought into direct contact with the semiconductor, it is preferable that the linear expansion coefficient of the insulating material is set to be close to the linear expansion coefficient of the semiconductor so that cracks are not generated due to a difference between the linear expansion coefficients in a high temperature environment.

Next, examples of a method of preparing conductive paste from the epoxy resin composition of the present invention include a method of obtaining a composition for an anisotropic conductive film by dispersing fine conductive particles in the epoxy resin composition and a method of obtaining a paste resin composition for connecting a circuit which is in a liquid state at room temperature or an anisotropic conductive adhesive.

As a method of preparing the epoxy resin composition of the present invention to a resin composition for an adhesive, a method of uniformly mixing the epoxy resin (A) and the phenol resin (B), and resins, the curing accelerator (C), a solvent, and an additive as necessary at room temperature under heating using a mixing mixer may be exemplified. Further, various base materials can be bonded by coating the base materials and allowing the base materials to stand under heating.

The cured product of the present invention is obtained by forming and curing the epoxy resin composition of the present invention described above and can be used as a laminate, a casting material, an adhesive, a coating film, or a film according to the applications thereof. As described above, the cured product is particularly useful as a copper clad laminated plate for a printed circuit board and a build-up film.

### EXAMPLES

Next, the present invention will be described in detail with reference to examples and comparative examples, and “part” and “%” described below are on a mass basis.

<GPC Measurement>

The measurement was carried out under the following conditions.

Measuring device: “HLC-8320 GPC”, manufactured by TOSOH CORPORATION

Column: Guard Column “HXL-L”, manufactured by TOSOH CORPORATION+“TSK-GEL G2000HXL”, manufactured by TOSOH CORPORATION+“TSK-GEL G2000HXL”, manufactured by TOSOH CORPORATION+“TSK-GEL G3000HXL”, manufactured by TOSOH CORPORATION+“TSK-GEL G4000HXL”, manufactured by TOSOH CORPORATION

Detector: RI (differential refractometry) detector

Data processing: “EcoSEC-WS VERSION 1.12”, manufactured by TOSOH CORPORATION

Measurement conditions: column temperature of 40° C., tetrahydrofuran used as developing solvent, flow rate of 1.0 ml/min

Standard: The following monodisperse polystyrene having a known molecular weight was used in conformity with the measurement manual of “EcoSEC-WS VERSION 1.12” described above.

(Polystyrene to be Used)

“A-1000” manufactured by TOSOH CORPORATION

“A-5000” manufactured by TOSOH CORPORATION

“F-2” manufactured by TOSOH CORPORATION

“F-4” manufactured by TOSOH CORPORATION

“F-20” manufactured by TOSOH CORPORATION

Sample: 1.0% by mass of tetrahydrofuran solution in terms of resin solid, which was filtered using microfilter (50 μl).

### Synthesis Example 1

883 parts of p-tertiary butyl phenol, 88 parts of melamine, 253 parts of 41.5% formalin, and 1.8 parts of triethylamine were added to a flask provided with a thermometer, a cooling tube, a fractionating column, and a stirrer, and the flask was gradually heated to 100° C. while paying attention to heat generation. The contents were reacted at 100° C. for 2 hours under reflux and then heated to 130° C. for 3 hours while water was removed under normal pressure. Next, the contents were reacted for 2 hours under reflux and then heated to 150° C. for 1 hour while water was removed under normal pressure. The contents were further reacted for 2 hours under reflux and then heated to 180° C. for 2 hours while water was removed under normal pressure. Next, unreacted p-tertiary butyl phenol was removed under reduced pressure, thereby obtaining a phenol resin (B-1). The GPC chart of the obtained phenol resin (B-1) is shown in FIG. 1. As shown in the GPC chart, the content of the bifunctional compound represented by Structural Formula (III) was 7.7% and the Mw/Mn was 1.56.

### Synthesis Example 2

A phenol resin (B-2) was obtained by performing the same operation as in Synthesis Example 1 except that 438 parts of p-tertiary butyl phenol, 63 parts of melamine, 106 parts of 41.5% formalin, and 1.8 parts of triethylamine were added. The GPC chart of the obtained phenol resin (B-2) is shown in FIG. 2. As shown in the GPC chart, the content of the bifunctional compound represented by Structural Formula (III) was 8.4% and the Mw/Mn was 1.42.

### Comparative Synthesis Example 1

A phenol resin (X-1) was obtained by performing the same operation as in Synthesis Example 1 except that 630 parts of p-tertiary butyl phenol and 1.3 parts of triethylamine in Synthesis Example 1 were changed to 395 parts of phenol and 0.8 parts of triethylamine. The GPC chart of the obtained phenol resin (X-1) is shown in FIG. 3. As shown in the GPC chart, the content of the bifunctional compound was 13.7% and the Mw/Mn was 2.02.

### Comparative Synthesis Example 2

A phenol resin (X-2) was obtained by performing the same operation as in Synthesis Example 1 except that 630 parts of p-tertiary butyl phenol and 1.3 parts of triethylamine in Synthesis Example 1 were changed to 454 parts of o-cresol and 0.9 parts of triethylamine.

### Examples 1 and 2 and Comparative Examples 1 and 2

The solubility in a solvent of each phenol resin obtained in the synthesis examples and comparative synthesis examples was evaluated in the following manner. The results are listed in Table 1.

<Test for Solubility in Solvent>

A methyl ethyl ketone (MEK) solution and a propylene glycol monomethyl ether acetate (PMA) solution having a non-volatile content of 40% by mass and having a non-volatile content of 60% by mass were prepared, a vial into which each of the phenol resins obtained in the synthesis examples and comparative synthesis examples was put was allowed to stand at room temperature for 180 days, and then the numbers of days taken until insoluble matter was deposited were compared to each other (a larger value indicates that the solubility in a solvent is more excellent). “X” in the table indicates that the content was not dissolved even when heated.

TABLE 1

| | | | | Comparative | Comparative |
|---|---|---|---|---|---|
| | Non-volatile | Example 1 | Example 2 | Example 1 | Example 2 |
| | content (%) | B-1 | B-2 | X-1 | X-2 |
| MEK | 60 | >180 | >180 | >180 | 30 |
| | 40 | >180 | >180 | >180 | 10 |
| PMA | 60 | >180 | >180 | >180 | >180 |
| | 40 | >180 | >180 | >180 | 60 |

### Examples 3 and 4 and Comparative Example 3

Various evaluation tests were performed after preparing the epoxy resin composition in the following manner and preparing laminated plates and films. The results are listed in Table 2.

<Preparation of Epoxy Resin Composition>

Each of the phenol resins obtained in the synthesis examples was blended with a cresol novolak type epoxy resin (“N-680” manufactured by DIC Corporation, epoxy group equivalent of 212 g/eq) such that the number of hydroxyl groups in each phenol resin was set to ½ of the molar number of the epoxy groups and the amount of the mixture was set to 100 g, 0.1% by mass of 2-ethyl-4-methylimidazole (“2E4MZ”, manufactured by SHIKOKU CHEMICALS CORPORATION) was added with respect to the total mass of the epoxy resin and the phenol resin, 20% by mass of spherical alumina (average particle diameter of 12.2 μm) was added with respect to the total mass of the epoxy resin and the phenol resin, and the non-volatile content was adjusted to 58% by mass using methyl ethyl ketone, thereby obtaining an epoxy resin composition.

<Preparation of Laminated Plate>

A laminated plate was prepared under the following conditions.

Base material: glass cloth “#2116” (210×280 mm), manufactured by Nitto Boseki Co., Ltd.

Number of plies: 6

Conditions for obtaining prepreg: 160° C.

Curing conditions: 200° C. and 40 kg/cm² for 1.5 hours

Plate thickness after molding: 0.8 mm

<Preparation of Film>

A film was prepared under the following conditions.

Base material: polyethylene terephthalate film (thickness of 38 μm)

Film thickness: 40 μm

Drying conditions: 100° C.

Curing conditions: 180° C. for 5 hours

<Glass Transition Temperature>

A cured product having a thickness of 0.8 mm was cut out from the laminated plate such that the width thereof was set to 5 mm and the length thereof was set to 54 mm and this cut-out piece was set to a test piece. The test piece was evaluated by setting the temperature at which a change in elastic modulus was the maximum (tan δ change rate was the maximum) as the glass transition temperature using a viscoelasticity measuring device (DMA: solid viscoelasticity measuring device “RSAII”, manufactured by Rheometric Scientific, Inc., rectangular tension method: frequency of 1 Hz, temperature rising rate of 3° C./min).

<Measurement of Dielectric Constant and Dielectric Tangent>

The dielectric constant and the dielectric tangent of the test piece which was stored in a chamber at a temperature of 23° C. and a humidity of 50% for 24 hours after bone dry were measured at 1 GHz using the laminated plate and a network analyzer “E8362C” (manufactured by Agilent Technologies, Inc.) according to a cavity resonance method in conformity with JIS-C-6481.

<Flame Retardancy>

A cured product having a thickness of 0.8 mm was cut out from the laminated plate such that the width thereof was set to 12.7 mm and the length thereof was set to 127 mm and this cut-out piece was set to a test piece. A combustion test was performed using 5 test pieces in conformity with UL-94 test method.
1: total combustion time of 5 test pieces (sec)
2: maximum combustion time in flame contact carried out once (sec)

<Thermal Conductivity>

The thermal conductivity of the film was measured using a thermal conductivity meter “QTM-500” (manufactured by KYOTO ELECTRONICS MANUFACTURING CO., LTD.) according to a transient hot wire method.

TABLE 2

| | | | | Comparative |
|---|---|---|---|---|
| Blending | | Example 3 | Example 4 | Example 3 |
| B-1 (PTBP) | g | 30 | | |
| B-2 (PTBP) | g | | 30 | |
| X-1 (phenol) | g | | | 29 |
| N-680 | g | 70 | 70 | 71 |
| 2E4MZ | g | 0.1 | 0.1 | 0.1 |
| Spherical alumina | g | 20 | 20 | 20 |
| Evaluation of physical | | | | |
| properties | | | | |
| Glass transition | ° C. | 223 | 235 | 210 |
| temperature Tg | | | | |
| (DMA) | | | | |
| Dielectric constant | | 3.6 | 3.5 | 4.1 |
| (1 GHz) | | | | |
| Dielectric tangent | | 0.012 | 0.011 | 0.016 |
| (1 GHz) | | | | |
| Flame retardancy | | V-0 | V-0 | V-1 |
| UL-94V | | | | |
| ΣF | sec | 18 | 23 | 121 |
| F max | sec | 3 | 5 | 18 |
| Thermal conductivity | W/(m · K) | 5.2 | 5.0 | 3.3 |

The abbreviation in the table is as follows.

PTBP: p-tertiary butyl phenol

### BRIEF DESCRIPTION OF DRAWINGS

FIG. 1 is a GPC chart of a phenol resin (B-1) obtained in Synthesis Example 1.

FIG. 2 is a GPC chart of a phenol resin (B-2) obtained in Synthesis Example 2.

FIG. 3 is a GPC chart of a phenol resin (X-1) obtained in Comparative Synthesis Example 1.

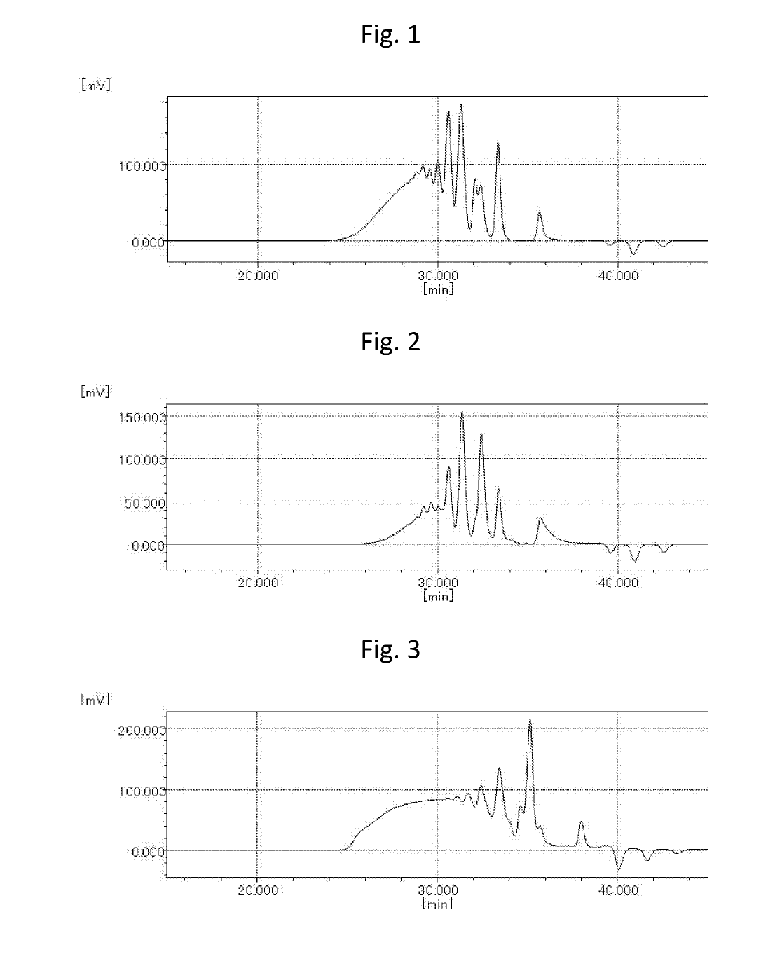

1. A triazine ring-containing phenol resin comprising:
a structural site α represented by the following Structural Formula (I) and a structural site β represented by the following Structural Formula (II), as repeating structural units: 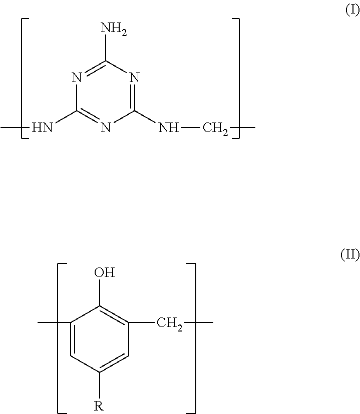
wherein R represents an alkyl group having 1 to 6 carbon atoms.

2. The triazine ring-containing phenol resin according to claim 1,
wherein the content of a bifunctional compound represented by the following Structural Formula (III) is from 1% to 12% in terms of a value calculated from the area ratio of a GPC chart: 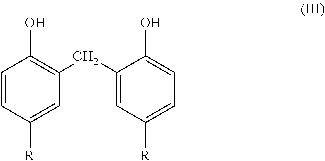
wherein R represents an alkyl group having 1 to 6 carbon atoms.

3. (canceled)

4. The triazine ring-containing phenol resin according to claim 1,
wherein R in Structural Formula (II) represents a tertiary butyl group.

5. (canceled)

6. An epoxy resin composition comprising:
an epoxy resin (A); and
a phenol resin (B),
wherein the phenol resin (B) is the triazine ring-containing phenol resin according to claim 1.

7. (canceled)

8. A cured product which is formed by curing the epoxy resin composition according to claim 6.

9-16. (canceled)
